(19) United States
(12) Patent Application Publication
(10) Pub. No.: US 2021/0405422 A1
(43) Pub. Date: Dec. 30, 2021

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Yantao LU, Wuhan, Hubei (CN); Zhifu LI, Wuhan, Hubei (CN); Jianfeng YUAN, Wuhan, Hubei (CN); Guanghui LIU, Wuhan, Hubei (CN); Chao WANG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 16/981,959

(22) PCT Filed: Jul. 22, 2020
(86) PCT No.: PCT/CN2020/103446

§ 371 Date: Sep. 17, 2020

(30) Foreign Application Priority Data
Jun. 29, 2020 (CN) 202010602523.9

(51) Int. Cl. G02F 1/1345; G02F 1/1362; H05K 1/18

(52) U.S. Cl. CPC G02F 1/13452; G02F 1/136286; H05K 2201/10136; G02F 2001/136222; H05K 1/189

(57) ABSTRACT

A display panel and a display device are provided. The display panel includes an array substrate and a color filter substrate. A plurality of drive chips are arranged at intervals and sequentially connected in series in a stepped region of the array substrate. The drive chip includes an input pin and an output pin. The lower frame of the display screen may be reduced, and the screen occupancy ratio of the display screen may be increased by disposing the input pins of the drive chip on one edge of the drive chip, and disposing the flexible circuit board on at least one edge of two edges of the drive chip.

### FIELD OF INVENTION

The present disclosure relates to the technical field of display, and more particularly, to the technical field of a display panel and a display device.

### BACKGROUND OF INVENTION

With the rapid development of portable electronic devices, people's requirement for display panels gradually increases. The design of narrow frames is a trend, especially in the design of large-sized and medium-sized high-resolution modules.

Please refer to FIG. 1. A conventional display panel adopts the solution of binding the drive chip is on the glass (IC on Glass, or COG) lower frame design. The display panel comprises an array substrate 11 and a color film substrate 12 disposed oppositely. The array substrate 11 comprises a display area 131 and a non-display area 132. The non-display area 132 comprises a stepped region 133. The stepped region 133 is provided with a plurality of drive chips 14 sequentially connected in series. Each of the drive chips 14 comprises an input pin 141 and an output pin 142. The input pin 141 is close to a flexible circuit board 15 and is disposed on an edge of the drive chip 14 away from the display area 131. The flexible circuit board 15 is disposed directly under the drive chip 14. The output pin 142 is disposed on an edge of the drive chip 14 close to the display area 131. A height of the lower frame of the display panel is a height of the stepped region 133. Therefore, the height of the lower frame of the display panel is a vertical distance D11 from the drive chip 14 to the display area 131+a height of the drive chip 14 D12+a vertical distance D13 from the flexible circuit board 15 to the drive chip 14+a height D14 of the flexible circuit board 15, thereby resulting in a large lower frame of the display panel.

In summary, it is necessary to provide a new display panel and display device to solve the technical problems described above.

### SUMMARY OF INVENTION

### Technical Problems

The display panel and the display device provided by the present disclosure solve the technical problem of the larger lower frame of the display panel due to the relative positional relationship between the drive chip and the flexible circuit board of the conventional large-sized and medium-sized display panel.

### Technical Solutions

To solve the problems described above, the technical solution provided by the present disclosure is described as follows.

One embodiment of the present disclosure provides a display panel. The display panel comprises an array substrate and a color filter substrate disposed oppositely. The array substrate comprises a display area and a non-display area adjacent to the display area.

The non-display area comprises a stepped region, and the stepped region is a region of the array substrate that extends beyond one edge of the color filter substrate. The stepped region is provided with a plurality of drive chips arranged at intervals and sequentially connected in series. The drive chip comprises an input pin and an output pin. The input pin is disposed on one edge of the drive chip, and the input pin is used to electrically connect with a connection terminal of a flexible circuit board corresponding to each of the drive chips. The output pin is used to electrically connect with the display area. The flexible circuit board is bent to a back of the display panel.

According to the display panel provided by one embodiment of the present disclosure, the input pin comprises a first input pin disposed on one edge of two edges of the drive chip. The connection terminal of the flexible circuit board comprises a first connection terminal. The first connection terminal and the first input pin are disposed on the same edge of the drive chip, and the first input pin is electrically connected with the first connection terminal.

According to the display panel provided by one embodiment of the present disclosure, the input pin further comprises a second input pin disposed on the other edge of two edges of the drive chip. The connection terminal of the flexible circuit board comprises a second connection terminal. The first connection terminal and the second input pin are disposed on the same edge of the drive chip. The second input pin is electrically connected with the second connection terminal.

According to the display panel provided by one embodiment of the present disclosure, the flexible circuit board comprises a main section and a connection section for connecting the input pin. The connection section comprises a first connection section correspondingly connected to the first input pin and a second connection section correspondingly connected to the second input pin. The first connection section and the second connection section are respectively located on each of two edges of the drive chip, and the connection terminals are disposed on the first connection section and the second connection section.

According to the display panel provided by one embodiment of the present disclosure, part of the output pins are disposed on one edge of the drive chip close to the display area, and at least part of the output pins are disposed on the drive chip away from one edge of the display area.

According to the display panel provided by one embodiment of the present disclosure, the stepped region is provided with a plurality of fan-out traces, and the output pins disposed on the drive chip away from one edge of the display area is connected to the display area through the fan-out traces from bottom to top.

According to the display panel provided by one embodiment of the present disclosure, a ratio of a number of the output pins disposed on the drive chip close to one edge of the display area to a number of total output pins is less than 50%.

According to the display panel provided by one embodiment of the present disclosure, the drive chip further comprises a plurality of serial connection pins. The serial connection pins are disposed on one edge of the drive chip, and the serial connection pins are disposed on the input pin close to one edge of the output pin.

According to the display panel provided by one embodiment of the present disclosure, a plurality of serial connection lines are further disposed between the two adjacent drive chips, and the serial connection lines are used to connect the serial connection pins.

One embodiment of the present disclosure provides a display panel. The display panel comprises a display panel, comprising an array substrate and a color filter substrate disposed oppositely. The array substrate comprises a display area and a non-display area adjacent to the display area.

The non-display area comprises a stepped region, and the stepped region is a region of the array substrate that extends beyond one edge of the color filter substrate; the stepped region is provided with a plurality of drive chips arranged at intervals and sequentially connected in series. The drive chip comprises an input pin and an output pin. The input pin is disposed on one edge of the drive chip, and the input pin is used to electrically connect with a connection terminal of a flexible circuit board corresponding to each of the drive chips. The output pin is used to electrically connect with the display area.

According to the display panel provided by one embodiment of the present disclosure, the input pin comprises a first input pin disposed on one edge of two edges of the drive chip. The connection terminal of the flexible circuit board comprises a first connection terminal. The first connection terminal and the first input pin are disposed on the same edge of the drive chip, and the first input pin is electrically connected with the first connection terminal.

According to the display panel provided by one embodiment of the present disclosure, the input pin further comprises a second input pin disposed on the other edge of two edges of the drive chip. The connection terminal of the flexible circuit board comprises a second connection terminal. The first connection terminal and the second input pin are disposed on the same edge of the drive chip, and the second input pin is electrically connected with the second connection terminal.

According to the display panel provided by one embodiment of the present disclosure, the flexible circuit board comprises a main section and a connection section for connecting the input pin. The connection section comprises a first connection section correspondingly connected to the first input pin and a second connection section correspondingly connected to the second input pin. The first connection section and the second connection section are respectively located on each of two edges of the drive chip, and the connection terminals are disposed on the first connection section and the second connection section.

According to the display panel provided by one embodiment of the present disclosure, part of the output pins are disposed on one edge of the drive chip close to the display area, and at least part of the output pins are disposed on the drive chip away from one edge of the display area.

According to the display panel provided by one embodiment of the present disclosure, the stepped region is provided with a plurality of fan-out traces, and the output pins disposed on the drive chip away from one edge of the display area is connected to the display area through the fan-out traces from bottom to top.

According to the display panel provided by one embodiment of the present disclosure, a ratio of a number of the output pins disposed on the drive chip close to one edge of the display area to a number of total output pins is less than 50%.

According to the display panel provided by one embodiment of the present disclosure, the drive chip further comprises a plurality of serial connection pins. The serial connection pins are disposed on one edge of the drive chip, and the serial connection pins are disposed on the input pin close to one edge of the output pin.

According to the display panel provided by one embodiment of the present disclosure, a plurality of serial connection lines are further disposed between the two adjacent drive chips, and the serial connection lines are used to connect the serial connection pins.

The present disclosure provides a display device, which comprises the display panel described above.

### Beneficial Effects

The beneficial effects of the present disclosure are that in the display panel and the display device provided by the present disclosure, by disposing the input pins of the drive chip on the edge of the drive chip, and placing the flexible circuit board on at least one of two edges of the drive chip, when the display panel adopts a COG design with the plurality of drive chips connected in series, the lower frame of the display screen becomes smaller, thereby increasing the screen-to-body ratio of the display screen since the height of the flexible circuit board, the vertical distance from the flexible circuit board to the drive chip, and the vertical distance from the flexible circuit board to the drive chip are reduced in the lower frame of the display panel.

### BRIEF DESCRIPTION OF DRAWINGS

In order to explain the embodiments or the technical solutions in the prior art more clearly, the following will briefly introduce the drawings that need to be used in the description of the embodiments or the prior art. Obviously, the drawings in the following description are merely some embodiments of the present disclosure, a person ordinarily skilled in the art can obtain other drawings based on these drawings without creative work.

FIG. 1 is a plane schematic view of a conventional display panel.

FIG. 2 is a plane schematic view of a first display panel according to one embodiment of the present disclosure.

FIG. 3 is a plane schematic view of a second display panel according to one embodiment of the present disclosure.

FIG. 4 is a plane schematic view of a third display panel according to one embodiment of the present disclosure.

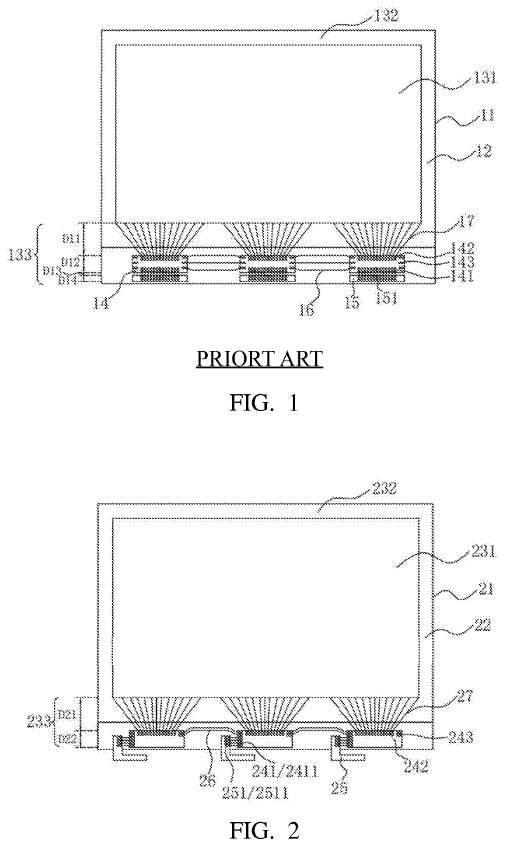

### DETAILED DESCRIPTION OF PREFERRED EMBODIMENTS

The descriptions of the following embodiments are referred to the attached drawings to exemplify specific embodiments in which the present disclosure may be implemented. The directional terms mentioned in the present disclosure, such as “up,” “down,” “front,” “back,” “left,” “right,” “inner,” “outer,” “edge” etc., are only the direction of the attached drawings. Therefore, the directional terms used are used to describe and understand the present disclosure, rather than to limit the present disclosure. In the figures, the units with similar structure are indicated by the same reference symbols.

In the present disclosure, it is appreciated that the indicated orientation or positional relationship of the terms “center,” “longitudinal,” “transverse,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” are based on the orientation or positional relationship shown in the drawings. The directions or positional relationships are only for the convenience of describing the present disclosure and simplifying the description, rather than indicating or implying that the device or element referred to must have a specific orientation, be constructed and operated in a specific orientation, and thus cannot be interpreted as a limitation of the present disclosure. Moreover, the terms “first” and “second” are only used for descriptive purposes and cannot be interpreted as indicating or implying relative significance or implicitly indicating the amount of technical features indicated. Accordingly, the defined “first” and “second” features may comprise one or more of the technical features explicitly or implicitly. In the description of the present disclosure, “a plurality of” means two or more than two, unless otherwise specifically defined.

In the description of the present disclosure, it should be noted that, unless otherwise clearly specified and limited, the terms “disposed,” “connected,” and “connection” should be interpreted in a broad sense. For example, it may be a fixed connection, a detachable connection, or an integral connection. It may be a mechanical connection, may also be an electrical connection, or may communicate with each other. It may be directly connected or indirectly connected through an intermediary. It may be the intercommunication between two elements or the interaction between two elements. A person ordinarily skilled in the art may understand the specific meanings of the technical terms described above in the present disclosure according to specific conditions.

In the present disclosure, unless otherwise clearly specified and limited, the first feature being “above” or “below” the second feature may comprise a condition that the first feature is direct contact with the second feature directly, or may also comprise a condition that the first feature is not direct contact with the second feature, but through an additional feature between the first feature and the second feature. Moreover, the first feature is “on,” “above,” and “upon” the second feature comprises a condition that the first feature is directly above and obliquely above the second feature, or simply means that the horizontal height of the first feature is higher than the horizontal height of the second feature. The first feature is “below,” “under,” and “beneath” the second feature comprises a condition that the first feature is directly below and obliquely below the second feature, or simply means that the horizontal height of the first feature is lower than the horizontal height of the second feature.

The following disclosure provides many different embodiments or examples for archiving different structures of the present disclosure. To simplify the disclosure of the present disclosure, the components and dispositions of specific examples are described below. Of course, they are only examples and are not intended to limit the present disclosure. In addition, the present disclosure may repeat reference numbers and/or reference letters in different examples, and such repetition is for the purpose of simplification and clarity, and does not indicate the relationship between the various implementations and/or disposition as discussed. In addition, the present disclosure provides examples of various specific processes and materials, but a person ordinarily skilled in the art may anticipate the application of other processes and/or the use of other materials.

The present disclosure aims at the conventional display panel and conventional display device having the larger lower frame of the display panel due to the relative positional relationship between the drive chip and the flexible circuit board. The present embodiment may solve the defect.

Please refer to FIG. 2. The display panel provided by the embodiment of the present disclosure comprises an array substrate 21 and a color filter substrate 22 disposed oppositely. The array substrate 21 comprises a display area 231 and a non-display area 232 adjacent to the display area 231. The display panel may be a liquid crystal display panel or an organic light-emitting diode display panel.

The non-display area 232 comprises a stepped region 233, and the stepped region 233 is a region of the array substrate 21 that extends beyond the color filter substrate 22. The stepped region 233 is also located in a region at a lower frame of the non-display area 232 of the display panel. The stepped region 233 is provided with a plurality of drive chips 24 arranged at intervals and sequentially connected in series. For the convenience of description, the stepped region 233 is provided with three drive chips 24 as an example for explanation, but the present disclosure does not limit the number of the drive chips 24, which may be two or more. The specific number may be determined based on the size of the display panel.

The drive chip 24 comprises an input pin 241 and an output pin 242. Each of the drive chips 24 is provided with a flexible circuit board 25 correspondingly. The input pin 241 is used to electrically connect a connection terminal 251 of the flexible circuit board 25. The output pin 242 is used to electrically connect the display area 231, so as to transmit a signal in the flexible circuit board 25 to the drive chip 24, and then transmit to the display area 231 from the drive chip 24, thereby archiving normal screen display.

In one embodiment of the present disclosure, the input pin 241 is disposed on one edge of the drive chip 24, that is, the input pin 241 is disposed on at least one of two edges of the drive chip 24 or at least one of them, so that a height of the stepped region 233 of the display panel is a vertical distance D21 from the drive chip 24 to the display area 231+a height D22 of the drive chip 24. Compared with the conventional display panel, the height of the stepped region 233 does not comprise a vertical distance D13 from the flexible circuit board 25 to the drive chip 24 and a height D14 of the flexible circuit board 25, so that the height of the lower frame may be greatly reduced.

Specifically, in one embodiment, the input pin 241 is disposed on one edge of two edges of the drive chip 24. Specifically, the input pin 241 comprises a first input pin 2411 disposed on one edge of two edges of the drive chip 24. Correspondingly, the connection terminal 251 of the flexible circuit board 25 is also disposed near one edge of the drive chip 24. The connection terminal 251 of the flexible circuit board 25 comprises a first connection terminal 2511. The first connection terminal 2511 and the first input pin 2411 are disposed near the same edge of the drive chip 24. The first input pin 2411 is electrically connected with the first connection terminal by a metal wire. The height of the lower frame of the display panel may not have the height of the flexible circuit board 25 and the vertical distance from the flexible circuit board 25 to the drive chip 24 by a manner of disposing both of the input pin 241 and the connection terminal 251 near the edge of the drive chip 24, thereby reducing the height of the lower frame and increasing the screen-to-body ratio of the display screen.

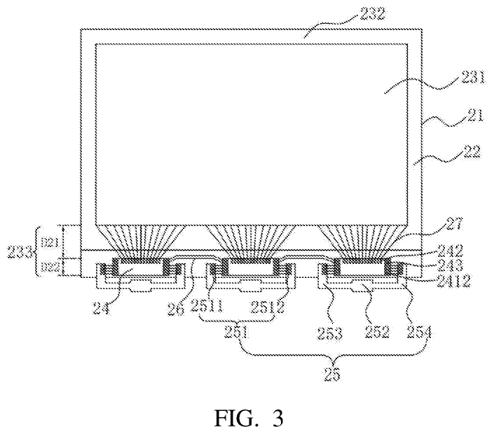

Please refer to FIG. 3, in another embodiment, to improve the integration of the display panel, based on the display panel shown in FIG. 2, the input pin 241 further comprise a second input pin 2412 disposed on the other of two edges of the drive chip 24. The first input pin 2411 and the second input pin 2412 are disposed oppositely. Correspondingly, the connection terminal 251 of the flexible circuit board 25 comprises a second connection terminal 2512. The first connection terminal 2511 and the second input pin 2412 are disposed near the same edge of the drive chip 24. The second input pin 2412 is electrically connected with the second connection terminal 2512 by a metal wire.

Specifically, the flexible circuit board 25 comprises a main section 252 and a connection section for connecting the input pin 241. The connection section comprises a first connection section 253 correspondingly connected to the first input pin 2411 and a second connection section 254 correspondingly connected to the second input pin 2412. The first connection section 253 and the second connection section 254 are respectively located near each of two edges of the drive chip 24, and the connection terminals 251 are disposed on the first connection section 253 and the second connection section 254. Specifically, the connection terminal 251 comprises the first connection terminal 2511 disposed on first connection section 253 and the second connection terminal 2512 disposed on the second connection section 254. The first connection terminal 2511 is electrically connected with the first connection the first input pin 2411 by a metal wire, and the second connection terminal 2512 is electrically connected with the second input pin 2412 a metal wire. The input pins are provided on both edges of the drive chip 24, which may make full use of the effective space of the drive chip 24, improve its integration, and reduce the height D22 of the drive chip 24, thereby further reducing the height of the lower frame and increasing the screen-to-body ratio of the display screen.

It is appreciated that the flexible circuit board 25 may be bent to the back of the display panel, so that the lower frame of the display panel does not have the height of the flexible circuit board 25, which reduces the lower frame to a certain extent.

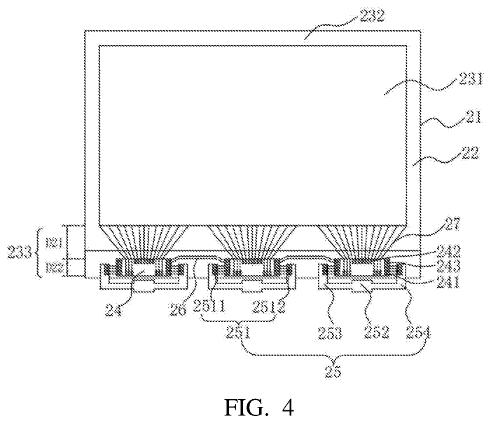

Please refer to FIG. 4. Further, since the input pin 241 is disposed on the edge of the drive chip 24, and a remaining space is present on the edge of the drive chip 24 away from the display area 231, at least part of the output pins 242 may be disposed on the edge of the drive chip 24 away from the display area 231, and part of the output pins 242 may be disposed on the edge of the drive chip 24 close to the display area 231. That is, by transferring at least part of the output pins 242 disposed on the edge of the drive chip 24 close to the display area 231 to the edge of the drive chip 24 away from the display area 231 may shorten the vertical distance between the drive chip 24 and the display area 231, which makes full use of the effective space of the metal wire and reduces the height of the lower frame. Moreover, the stepped area 233 is provided with a plurality of fan-out traces 27, and the output pins 242 disposed on the edge away from the display area 231 are connected to the display area 231 through the fan-out traces 27 from bottom to top, which effectively use the height of metal wire.

Specifically, the ratio of the number of the output pins 242 disposed on the edge of the drive chip 24 close to the display area 231 to the number of total output pins is less than 50%.

Please refer to FIG. 2, FIG. 3, and FIG. 4. The drive chip 24 further comprises a plurality of serial connection pins 243. The serial connection pins 243 are disposed on the edge of the drive chip 24, and the serial connection pins 243 are disposed on the input pin 241 close to one edge of the output pin 242. A plurality of serial connection lines 26 are further disposed between the two adjacent drive chips 24, and the serial connection wires 26 are used to connect the serial connection pins 243, so that the plurality of drive chips 24 may work together, transmit signals between each other, and work synchronously.

One embodiment of the present disclosure also provides a display device. The display device comprises the display panel in the embodiment mentioned above. The display device may be a display device such as a mobile terminal, a tablet computer, a notebook, a television, and an all-in-one computer.

The beneficial effects are that in the display panel and the display device provided by the embodiments of the present disclosure, by disposing the input pins of the drive chip on the edge of the drive chip, and placing the flexible circuit board on at least one of two edges of the drive chip, when the display panel adopts a COG design with the plurality of drive chips connected in series, the lower frame of the display screen becomes smaller, thereby increasing the screen-to-body ratio of the display screen since the height of the flexible circuit board, the vertical distance from the flexible circuit board to the drive chip, and the vertical distance from the flexible circuit board to the drive chip are reduced in the lower frame of the display panel.

In summary, although the present disclosure has been disclosed as above in preferred embodiments, the above-mentioned preferred embodiments are not intended to limit the present disclosure. A person ordinarily skilled in the art can make various changes and modifications without departing from the concept and scope of the present disclosure. Therefore, the claimed scope of the present disclosure based on the scope defined by the claims.

1. A display panel, comprising:
an array substrate and a color filter substrate disposed oppositely, wherein the array substrate comprises a display area and a non-display area adjacent to the display area,
wherein the non-display area comprises a stepped region, and the stepped region is a region of the array substrate that extends beyond one edge of the color filter substrate; the stepped region is provided with a plurality of drive chips arranged at intervals and sequentially connected in series, wherein the drive chip comprises an input pin and an output pin, the input pin is disposed on one edge of the drive chip, and the input pin is used to electrically connect with a connection terminal of a flexible circuit board corresponding to each of the drive chips, wherein the output pin is disposed on another edge of the drive chip adjacent to and perpendicular to the one edge of the drive chip, the another edge of the drive chip is disposed opposite to the display area, and the output pin is used to electrically connect with the display area, and the flexible circuit board is bent to a back of the display panel.

2. The display panel according to claim 1, wherein the input pin comprises a first input pin disposed on one edge of edges of the drive chip, wherein the connection terminal of the flexible circuit board comprises a first connection terminal, and the first connection terminal and the first input pin are disposed near the same edge of the drive chip, and the first input pin is electrically connected with the first connection terminal.

3. The display panel according to claim 2, wherein the input pin further comprises a second input pin disposed on another edge of two edges of the drive chip, wherein the connection terminal of the flexible circuit board comprises a second connection terminal, and the first connection terminal and the second input pin are disposed near the same edge of the drive chip, and the second input pin is electrically connected with the second connection terminal.

4. The display panel according to claim 3, wherein the flexible circuit board comprises a main section and a connection section for connecting the input pin, wherein the connection section comprises a first connection section correspondingly connected to the first input pin and a second connection section correspondingly connected to the second input pin; the first connection section and the second connection section are respectively located on each of two edges of the drive chip, and the connection terminals are disposed on the first connection section and the second connection section.

5. The display panel according to claim 1, wherein part of the output pins are disposed on one edge of the drive chip close to the display area, and at least part of the output pins are disposed on the drive chip away from one edge of the display area.

6. The display panel according to claim 5, wherein the stepped region is provided with a plurality of fan-out traces, and the output pins disposed on the drive chip away from one edge of the display area is connected to the display area through the fan-out traces.

7. The display panel according to claim 5, wherein a ratio of a number of the output pins disposed on the drive chip close to one edge of the display area to a number of total output pins is less than 50%.

8. The display panel according to claim 1, wherein the drive chip further comprises a plurality of serial connection pins, the serial connection pins are disposed on one edge of the drive chip, and the serial connection pins are disposed on the input pin close to one edge of the output pin.

9. The display panel according to claim 8, wherein a plurality of serial connection lines are further disposed between the two adjacent drive chips, and the serial connection lines are used to connect the serial connection pins.

10. (canceled)

11. (canceled)

12. (canceled)

13. (canceled)

14. (canceled)

15. (canceled)

16. (canceled)

17. (canceled)

18. (canceled)

19. A display device, comprising a display panel according to claim 1.
